(19) United States
(12) Patent Application Publication
(10) Pub. No.: US 2006/0065189 A1
(43) Pub. Date: Mar. 30, 2006

(54) Method and system for homogenization of supercritical fluid in a high pressure processing system

(76) Inventors: Darko Babic, Chandler, AZ (US); Gentaro Goshi, Phoenix, AZ (US)

Correspondence Address: WOOD, HERRON & EVANS, LLP (TOKYO ELECTRON), 2700 CAREW TOWER, 441 VINE STREET, CINCINNATI, OH, 45202, US

(21) Appl. No.: 10/955,325

(22) Filed: Sep. 30, 2004

(51) Int. Cl. B08B 7/04; C23C 14/00; B08B 3/00; B05C 11/00

(52) U.S. Cl. 118/50; 134/10; 134/56 R; 118/688

(57) ABSTRACT

A method and system for providing a homogeneous processing environment in a high pressure processing system is described. A high pressure fluid and a process chemistry are mixed in a pre-mixing system prior to exposure with the fluid in a supercritical state of a substrate in the high pressure processing system. For example, the pre-mixing system can include a fluid circulation system configured to bypass the high pressure processing system until the high pressure fluid and the process chemistry are mixed. Alternatively, the pre-mixing system can include a mixing chamber, and optionally include means for agitating the high pressure fluid and process chemistry in the mixing chamber.

This application is related to U.S. patent application filed as Express Mail No.: EV536052723US, filed on even date herewith, hereby expressly incorporated by reference herein.

### BACKGROUND OF THE INVENTION

1. Field of the Invention

The present invention relates to a method and apparatus for providing a homogeneous processing environment in a high pressure processing system and, more particularly, to a method and apparatus for mixing a high pressure fluid and a process additive prior to exposure to a substrate in a high pressure processing system.

2. Description of Related Art

During the fabrication of semiconductor devices for integrated circuits (ICs), a critical processing requirement for processing semiconductor devices is cleanliness. The processing of semiconductor devices includes vacuum processing, such as etch and deposition processes whereby material is removed from or added to a substrate surface, as well as atmospheric processing, such as wet cleaning whereby contaminants or residue accumulated during processing are removed. For example, the removal of residue, such as photoresist, hardened photoresist, post-etch residue, and post-ash residue subsequent to the etching of features, such as trenches or vias, can utilize dry plasma ashing with an oxygen plasma followed by wet cleaning.

Until recently, dry plasma ashing and wet cleaning were found to be sufficient for removing residue and contaminants accumulated during semiconductor processing. However, recent advancements for ICs include a reduction in the critical dimension for etched features below a feature dimension acceptable for wet cleaning, such as a feature dimension below 45- to to 65 nanometers, as well as the introduction of new materials, such as low dielectric constant (low-k) materials, which are susceptible to damage during plasma ashing.

Therefore, at present, interest has developed for the replacement of dry plasma ashing and wet cleaning. One interest includes the development of dry cleaning systems utilizing a supercritical fluid as a carrier for a process additive, such as a solvent or other residue removing composition. Post-etch and post-ash cleaning are examples of such systems. Other interests include other processes and applications that can benefit from the properties of supercritical fluids, particularly of substrates having features with a dimension of 65 nm, or 45 nm, or smaller. Such processes and applications may include restoring low dielectric films after etching, sealing porous films, drying of applied films, depositing materials, as well as other processes and applications. At present, the inventors have recognized that conventional high pressure processing systems offer insufficient control of the introduction of the process additive to the supercritical fluid which leads to a non-homogeneous processing environment during treatment of a substrate. Consequently, the substrate is exposed to variations in the concentration of the process additive that can cause excessive cleaning and potential damage at times, as well as poor cleaning at other times.

### SUMMARY OF THE INVENTION

One aspect of the invention is to reduce or eliminate any or all of the above-described problems.

Another object of the invention is to provide a method and system for providing a homogeneous processing environment in a high pressure processing system.

Another object of the invention is to provide a method and system for mixing a high pressure fluid and a process additive in a high pressure processing system.

According to one aspect, a high pressure processing system for treating a substrate is described comprising: a processing chamber configured to treat the substrate with a fluid, introduced therein, having substantially supercritical fluid properties; a high pressure fluid supply system configured to introduce a high pressure fluid to the processing chamber; a process chemistry supply system configured to introduce a process chemistry to the processing chamber; a pre-mixing system coupled to the processing chamber, and configured to receive the high pressure fluid from the high pressure fluid supply system and the process chemistry from the process chemistry supply system and mix the high pressure fluid and the process chemistry prior to introducing the high pressure fluid and the process chemistry to the processing chamber; and a fluid flow system coupled to the processing chamber, and configured to circulate the high pressure fluid and the process chemistry through the processing chamber over the substrate.

According to another aspect, a method of processing a substrate in a high pressure processing system is described comprising: supplying a high pressure fluid for use in the high pressure processing system; supplying a process chemistry for use in the high pressure processing system; mixing the high pressure fluid and the process chemistry prior to introducing the high pressure fluid and the process chemistry to the high pressure processing system; introducing the high pressure fluid and the process chemistry to the high pressure processing system; and exposing the substrate to the high pressure fluid and the process chemistry in the high pressure processing system by bringing the fluid to a state having substantially supercritical fluid properties and exposing the substrate to the fluid in that state.

### BRIEF DESCRIPTION OF THE DRAWINGS

In the accompanying drawings:

FIG. 1 presents a simplified schematic representation of a high pressure processing system according to an embodiment of the invention;

FIG. 2 presents a simplified schematic representation of a high pressure processing system according to another embodiment of the invention;

FIG. 3 presents a simplified schematic representation of a high pressure processing system according to another embodiment of the invention;

FIG. 4 presents a simplified schematic representation of a high pressure processing system according to yet another embodiment of the invention; and

FIG. 5 illustrates a method of processing a substrate in a high pressure processing system according to an embodiment of the invention.

### DETAILED DESCRIPTION OF EXEMPLARY EMBODIMENTS

In the following description, to facilitate a thorough understanding of the invention and for purposes of explanation and not limitation, specific details are set forth, such as a particular geometry of the high pressure processing system and various descriptions of the system components. However, it should be understood that the invention may be practiced with other embodiments that depart from these specific details.

Nonetheless, it should be appreciated that, contained within the description are features which, notwithstanding the inventive nature of the general concepts being explained, are also of an inventive nature.

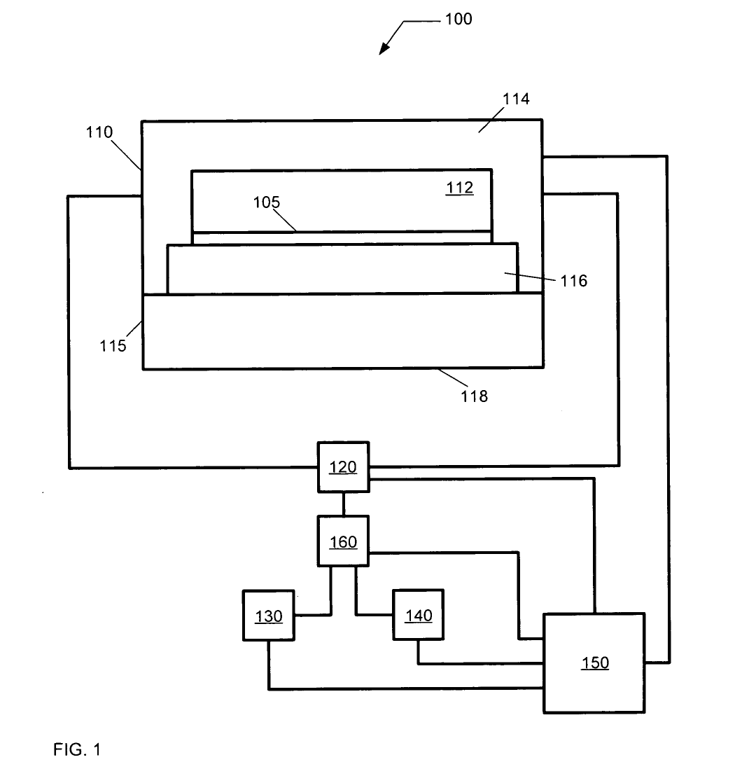

Referring now to the drawings, wherein like reference numerals designate identical or corresponding parts throughout the several views, FIG. 1 illustrates a high pressure processing system 100 according to an embodiment of the invention. In the illustrated embodiment, high pressure processing system 100 comprises processing elements that include a processing chamber 110, a fluid flow system 120, a pre-mixing system 160, a process chemistry supply system 130, a high pressure fluid supply system 140, and a controller 150, all of which are configured to process substrate 105. The controller 150 can be coupled to the processing chamber 110, the fluid flow system 120, the pre-mixing system 160, the process chemistry supply system 130, and the high pressure fluid supply system 140. Alternately, or in addition, controller 150 can be coupled to a one or more additional controllers/computers (not shown), and controller 150 can obtain setup and/or configuration information from an additional controller/computer.

In FIG. 1, singular processing elements (110, 120, 130, 140, 150, and 160) are shown, but this is not required for the invention. The high pressure processing system 100 can comprise any number of processing elements having any number of controllers associated with them in addition to independent processing elements.

The controller 150 can be used to configure any number of processing elements (110, 120, 130, 140, and 160), and the controller 150 can collect, provide, process, store, and display data from processing elements. The controller 150 can comprise a number of applications for controlling one or more of the processing elements. For example, controller 150 can include a graphic user interface (GUI) component (not shown) that can provide easy to use interfaces that enable a user to monitor and/or control one or more processing elements.

Referring still to FIG. 1, the fluid flow system 120 is configured to flow fluid and chemistry from the supplies 130 and 140 through the chamber 110. The fluid flow system 120 is illustrated as a recirculation system through which the fluid and chemistry recirculate from and back to the chamber 110. This recirculation is most likely to be the preferred configuration for many applications, but this is not necessary to the invention. Fluids, particularly inexpensive fluids, can be passed through the chamber once then discarded, which might be more efficient than reconditioning them for reentry into the chamber. Accordingly, while the fluid flow system is described as a recirculating system in the exemplary embodiments, a non-recirculating system may, in some cases, be substituted. This fluid flow system or recirculation system 120 can include one or more valves for regulating the flow of a high pressure processing solution through the recirculation system 120 and through the processing chamber 110. The recirculation system 120 can comprise any number of back-flow valves, filters, pumps, and/or heaters (not shown) for maintaining a high pressure processing solution and flowing the high pressure process solution through the recirculation system 120 and through the processing chamber 110.

Referring still to FIG. 1, the high pressure processing system 100 can comprise high pressure fluid supply system 140. The high pressure fluid supply system 140 can be coupled to the recirculation system 120 via pre-mixing system 160, but this is not required. In alternate embodiments, high pressure fluid supply system supply system 140 can be configured differently and coupled differently. For example, the high pressure fluid supply system 140 can be coupled to the processing chamber 110 via pre-mixing system 160. The fluid supply system 140 can include a supercritical fluid supply system. A supercritical fluid as referred to herein is a fluid that is in a supercritical state, which is that state that exists when the fluid is maintained at or above the critical pressure and at or above a critical temperature on its phase diagram, which pressure is typically also temperature dependent. In such a supercritical state, the fluid possesses certain properties, one of which is the substantial absence of a surface tension. Accordingly, a supercritical fluid supply system, as referred to herein, is one that delivers to a processing chamber a fluid that assumes a supercritical state at the pressure and temperature at which the processing chamber is being controlled. Furthermore, it is only necessary that at least at or near the critical point so that the fluid is in a substantially supercritical state at which its properties are sufficient, and exist long enough, to realize their advantages in the process being performed. Carbon dioxide, for example, is a supercritical fluid when maintained at or above a pressure of about 1070 psi at a temperature of 31 degrees C., a pressure that varies inversely with temperature. This state of the fluid in the processing chamber may be maintained by operating the chamber at 2,000 to 6,000 psi at a temperature of between 60 and 100 degrees C., for example.

The high pressure fluid supply system 140 can include a supercritical fluid supply system, which can be a carbon dioxide supply system. The high pressure fluid supply system 140 can be configured to introduce a high pressure fluid having a pressure substantially near the critical pressure for the fluid. Additionally, the high pressure fluid supply system 140 can be configured to introduce a supercritical fluid, such as carbon dioxide in a supercritical state. Examples of other supercritical fluid species useful in the broad practice of the invention include, but are not limited to, carbon dioxide (as described above), oxygen, argon, krypton, xenon, ammonia, methane, methanol, dimethyl ketone, hydrogen, and sulfur hexafluoride. The high pressure fluid supply system can, for example, comprise a carbon dioxide source (not shown) and a plurality of flow control elements (not shown) for generating a supercritical fluid. For example, the carbon dioxide source can include a CO₂ feed system, and the flow control elements can include supply lines, valves, filters, pumps, and heaters. The high pressure fluid supply system 140 can comprise an inlet valve (not shown) that is configured to open and close to allow or prevent the stream of supercritical carbon dioxide from flowing into the processing chamber 110. For example, controller 150 can be used to determine fluid parameters such as pressure, temperature, process time, and flow rate.

Referring still to FIG. 1, the process chemistry supply system 130 is coupled to the recirculation system 120 via pre-mixing system 160, but this is not required for the invention. In alternate embodiments, the process chemistry supply system 130 can be coupled to the processing chamber 110 via pre-mixing system 160. Alternatively, the process chemistry supply system 130 can be coupled to different elements in the high pressure processing system 100 via the pre-mixing system 160. The process chemistry is introduced by the process chemistry supply system 130 into the fluid introduced by the fluid supply system 140 at ratios that vary with the substrate properties, the chemistry being used and the process being performed in the chamber. Usually the ratio is roughly 1 to 5 percent by volume, which, for a chamber, recirculation system and associated plumbing having a volume of about 1 liter amounts to about 10 to 50 milliliter of additive in most cases, but the ratio may be higher or lower.

The process chemistry supply system 100 can be configured to introduce one or more of the following process compositions, but not limited to: cleaning compositions for removing contaminants, residues, hardened residues, photoresist, hardened photoresist, post-etch residue, post-ash residue, post chemical-mechanical polishing (CMP) residue, post-polishing residue, or post-implant residue, or any combination thereof; cleaning compositions for removing particulate; drying compositions for drying thin films, porous thin films, porous low dielectric constant materials, or air-gap dielectrics, or any combination thereof; film-forming compositions for preparing dielectric thin films, metal thin films, or any combination thereof; or any combination thereof. Additionally, the process chemistry supply system 130 can be configured to introduce solvents, co-solvents, surfactants, film-forming precursors, or reducing agents, or any combination thereof.

The process chemistry supply system 130 can be configured to introduce N-Methyl Pyrrolidone (NMP), diglycol amine, hydroxylamine, di-isopropyl amine, tri-isoprpyl amine, tertiary amines, catechol, ammonium fluoride, ammonium bifluoride, methylacetoacetamide, ozone, propylene glycol monoethyl ether acetate, acetylacetone, dibasic esters, ethyl lactate, CHF₃, BF₃, HF, other fluorine containing chemicals, or any mixture thereof. Other chemicals such as organic solvents may be utilized independently or in conjunction with the above chemicals to remove organic materials. The organic solvents may include, for example, an alcohol, ether, and/or glycol, such as acetone, diacetone alcohol, dimethyl sulfoxide (DMSO), ethylene glycol, methanol, ethanol, propanol, or isopropanol (IPA). For further details, see U.S. Pat. No. 6,306,564B1, filed May 27, 1998, and titled “REMOVAL OF RESIST OR RESIDUE FROM SEMICONDUCTORS USING SUPERCRITICAL CARBON DIOXIDE”, and U.S. Pat. No. 6,509,141B2, filed Sep. 3, 1999, and titled “REMOVAL OF PHOTORESIST AND PHOTORESIST RESIDUE FROM SEMICONDUCTORS USING SUPERCRITICAL CARBON DIOXIDE PROCESS,” both incorporated by reference herein.

Additionally, the process chemistry supply system 130 can comprise a cleaning chemistry assembly (not shown) for providing cleaning chemistry for generating supercritical cleaning solutions within the processing chamber. The cleaning chemistry can include peroxides and a fluoride source. For example, the peroxides can include hydrogen peroxide, benzoyl peroxide, or any other suitable peroxide, and the fluoride sources can include fluoride salts (such as ammonium fluoride salts), hydrogen fluoride, fluoride adducts (such as organo-ammonium fluoride adducts), and combinations thereof. Further details of fluoride sources and methods of generating supercritical processing solutions with fluoride sources are described in U.S. patent application Ser. No. 10/442,557, filed May 20, 2003, and titled “TETRA-ORGANIC AMMONIUM FLUORIDE AND HF IN SUPERCRITICAL FLUID FOR PHOTORESIST AND RESIDUE REMOVAL”, and U.S. patent application Ser. No. 10/321,341, filed Dec. 16, 2002, and titled “FLUORIDE IN SUPERCRITICAL FLUID FOR PHOTORESIST POLYMER AND RESIDUE REMOVAL,” both incorporated by reference herein.

Furthermore, the process chemistry supply system 130 can be configured to introduce chelating agents, complexing agents and other oxidants, organic and inorganic acids that can be introduced into the supercritical fluid solution with one or more carrier solvents, such as N,N-dimethylacetamide (DMAc), gamma-butyrolactone (BLO), dimethyl sulfoxide (DMSO), ethylene carbonate (EC), N-methylpyrrolidone (NMP), dimethylpiperidone, propylene carbonate, and alcohols (such a methanol, ethanol and 2-propanol).

Moreover, the process chemistry supply system 130 can comprise a rinsing chemistry assembly (not shown) for providing rinsing chemistry for generating supercritical rinsing solutions within the processing chamber. The rinsing chemistry can include one or more organic solvents including, but not limited to, alcohols and ketone. In one embodiment, the rinsing chemistry can comprise sulfolane, also known as thiocyclopenatne-1,1-dioxide, (Cyclo) tetramethylene sulphone and 2,3,4,5-tetrahydrothiophene-1,1-dioxide, which can be purchased from a number of venders, such as Degussa Stanlow Limited, Lake Court, Hursley Winchester SO21 2LD UK.

Moreover, the process chemistry supply system 130 can be configured to introduce treating chemistry for curing, cleaning, healing, or sealing, or any combination, low dielectric constant films (porous or non-porous). The chemistry can include hexamethyldisilazane (HMDS), chlorotrimethylsilane (TMCS), or trichloromethylsilane (TCMS). For further details, see U.S. patent application Ser. No. 10/682,196, filed Oct. 10, 2003, and titled “METHOD AND SYSTEM FOR TREATING A DIELECTRIC FILM,” and U.S. patent application Ser. No. 10/379,984, filed Mar. 4, 2003, and titled “METHOD OF PASSIVATING LOW DIELECTRIC MATERIALS IN WAFER PROCESSING,” both incorporated by reference herein.

The pre-mixing system 160 can include any system designed to mix the high pressure fluid supplied from the high pressure fluid supply system 140, and the process chemistry from the process chemistry supply system 130. The mixing of the high pressure fluid and the process chemistry is performed prior to exposing the substrate to any process chemistry. The high pressure fluid can include a supercritical fluid. Alternatively, the high pressure fluid includes carbon dioxide. Alternatively, the high pressure fluid includes supercritical carbon dioxide. Alternatively, the high pressure fluid includes liquefied carbon dioxide. The mixing of the high pressure fluid and the process chemistry can be performed in order to maintain the high pressure fluid in a supercritical state.

The processing chamber 110 can be configured to process substrate 105 by exposing the substrate 105 to high pressure fluid from the high pressure fluid supply system 140, or process chemistry from the process chemistry supply system 130, or a combination thereof in a processing space 112. Additionally, processing chamber 110 can include an upper chamber assembly 114, and a lower chamber assembly 115.

The upper chamber assembly 112 can comprise a heater (not shown) for heating the processing chamber 110, the substrate 105, or the processing fluid, or a combination of two or more thereof. Alternately, a heater is not required. Additionally, the upper chamber assembly can include flow components for flowing a processing fluid through the processing chamber 110. In one example, a circular flow pattern can be established, and in another example, a substantially linear flow pattern can be established. Alternately, the flow components for flowing the fluid can be configured differently to affect a different flow pattern.

The lower chamber assembly 115 can include a platen 116 configured to support substrate 105 and a drive mechanism 118 for translating the platen 116 in order to load and unload substrate 105, and seal lower chamber assembly 115 with upper chamber assembly 114. The platen 116 can also be configured to heat or cool the substrate 105 before, during, and/or after processing the substrate 105. Additionally, the lower assembly 115 can include a lift pin assembly for displacing the substrate 105 from the upper surface of the platen 116 during substrate loading and unloading.

A transfer system (not shown) can be used to move a substrate into and out of the processing chamber 110 through a slot (not shown). In one example, the slot can be opened and closed by moving the platen, and in another example, the slot can be controlled using a gate valve.

The substrate can include semiconductor material, metallic material, dielectric material, ceramic material, or polymer material, or a combination of two or more thereof. The semiconductor material can include Si, Ge, Si/Ge, or GaAs. The metallic material can include Cu, Al, Ni, Pb, Ti, and Ta. The dielectric material can include silica, silicon dioxide, quartz, aluminum oxide, sapphire, low dielectric constant materials, Teflon, and polyimide. The ceramic material can include aluminum oxide, silicon carbide, etc.

The processing system 100 can also comprise a pressure control system (not shown). The pressure control system can be coupled to the processing chamber 110, but this is not required. In alternate embodiments, the pressure control system can be configured differently and coupled differently. The pressure control system can include one or more pressure valves (not shown) for exhausting the processing chamber 110 and/or for regulating the pressure within the processing chamber 110. Alternately, the pressure control system can also include one or more pumps (not shown). For example, one pump may be used to increase the pressure within the processing chamber, and another pump may be used to evacuate the processing chamber 110. In another embodiment, the pressure control system can comprise seals for sealing the processing chamber. In addition, the pressure control system can comprise an elevator for raising and lowering the substrate and/or the platen.

Furthermore, the processing system 100 can comprise an exhaust control system. The exhaust control system can be coupled to the processing chamber 110, but this is not required. In alternate embodiments, exhaust control system can be configured differently and coupled differently. The exhaust control system can include an exhaust gas collection vessel (not shown) and can be used to remove contaminants from the processing fluid. Alternately, the exhaust control system can be used to recycle the processing fluid.

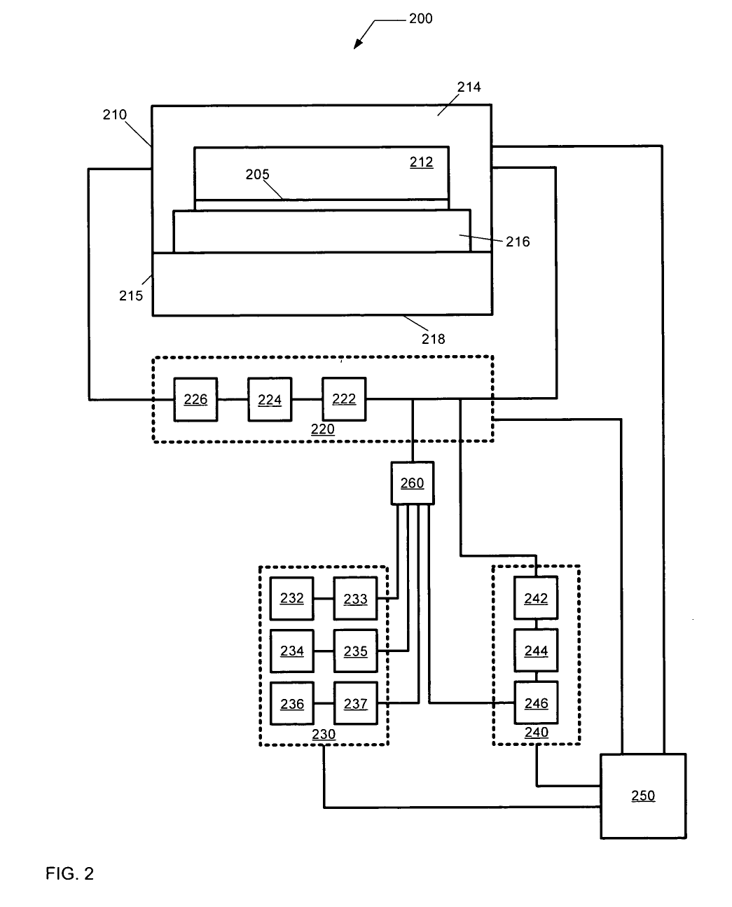

Referring now to FIG. 2, a high pressure processing system 200 is presented according to another embodiment. In the illustrated embodiment, high pressure processing system 200 comprises a processing chamber 210, a recirculation system 220, a pre-mixing system 260, a process chemistry supply system 230, a high pressure fluid supply system 240, and a controller 250, all of which are configured to process substrate 205. The controller 250 can be coupled to the processing chamber 210, the recirculation system 220, the pre-mixing system 260, the process chemistry supply system 230, and the high pressure fluid supply system 240. Alternately, controller 250 can be coupled to a one or more additional controllers/computers (not shown), and controller 250 can obtain setup and/or configuration information from an additional controller/computer.

As shown in FIG. 2, the recirculation system 220 can include a recirculation fluid heater 222, a pump 224, and a filter 226. Additionally, the process chemistry supply system 230 can include one or more chemistry introduction systems, each introduction system having a chemical source 232, 234, 236, and an injection system 233, 235, 237. The injection systems 233, 235, 237 can include a pump and an injection valve. Furthermore, the high pressure fluid supply system 240 can include a supercritical fluid source 242, a pumping system 244, and a supercritical fluid heater 246. Moreover, one or more injection valves, or exhaust valves may be utilized with the high pressure fluid supply system.

The pre-mixing system 260 can include any system designed to mix the high pressure fluid supplied from the high pressure fluid supply system 240, and the process chemistry from the process chemistry supply system 230. The mixing of the high pressure fluid and the process chemistry is performed prior to exposing the substrate to any process chemistry. The high pressure fluid can include a supercritical fluid. Alternatively, the high pressure fluid includes carbon dioxide. Alternatively, the high pressure fluid includes liquefied carbon dioxide. Alternatively, the high pressure fluid includes supercritical carbon dioxide. The mixing of the high pressure fluid and the process chemistry can be performed in order to maintain the high pressure fluid in a supercritical state.

Moreover, the high pressure processing system can include the system described in pending U.S. patent application Ser. No. 09/912,844 (US Patent Application Publication No. 2002/0046707 A1), entitled “High pressure processing chamber for semiconductor substrates”, and filed on Jul. 24, 2001, which is incorporated herein by reference in its entirety.

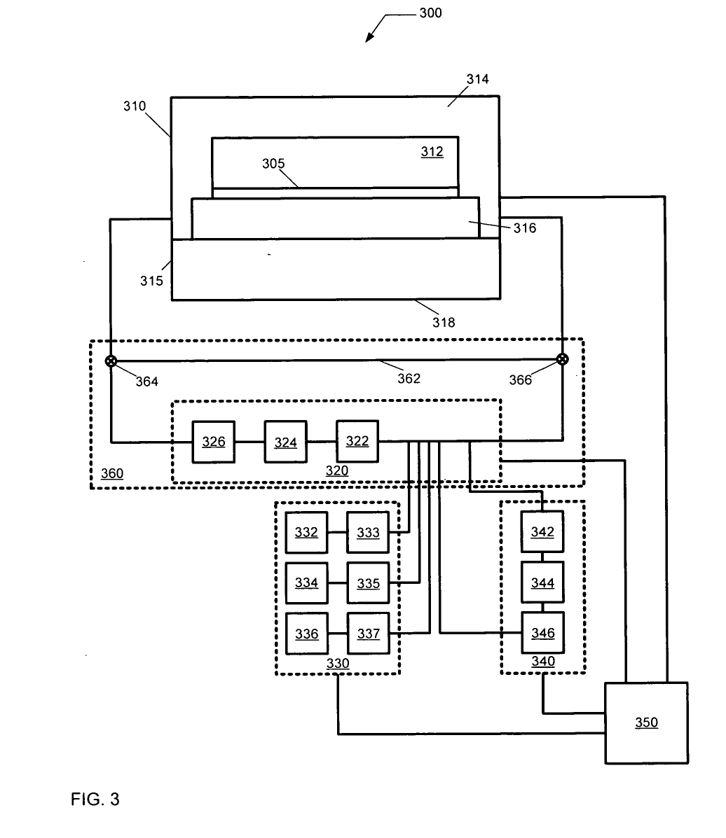

Referring now to FIG. 3, a high pressure processing system 300 is presented according to another embodiment. In the illustrated embodiment, high pressure processing system 300 comprises a processing chamber 310, a recirculation system 320, a pre-mixing system 360, a process chemistry supply system 330, a high pressure fluid supply system 340, and a controller 350, all of which are configured to process substrate 305. The controller 350 can be coupled to the processing chamber 310, the recirculation system 320, the pre-mixing system 360, the process chemistry supply system 330, and the high pressure fluid supply system 340. Alternately, controller 350 can be coupled to a one or more additional controllers/computers (not shown), and controller 350 can obtain setup and/or configuration information from an additional controller/computer.

As shown in FIG. 3, the recirculation system 320 can include a recirculation fluid heater 322, a pump 324, and a filter 326. Additionally, the process chemistry supply system 330 can include one or more chemistry introduction systems, each introduction system having a chemical source 332, 334, 336, and an injection system 333, 335, 337. The injection systems 333, 335, 337 can include a pump and an injection valve. Furthermore, the high pressure fluid supply system 340 can include a supercritical fluid source 342, a pumping system 344, and a supercritical fluid heater 346. Moreover, one or more injection valves, or exhaust valves may be utilized with the high pressure fluid supply system.

Also shown in FIG. 3, the pre-mixing system 360 comprises a bypass line 362, and one or more valves, such as a first valve 364 and a second valve 366. The first and second valves 364, 366 can include three-way valves. When the valves are closed to flow through processing chamber 310, the flow of high pressure fluid and process chemistry passes through bypass line 362, and it is circulated using pump 324 of recirculation system 320. The bypass line 362 can be designed to comprise a small volume compared to the volume of the processing chamber 310 and the volume of the plumbing outside of the processing chamber (such as inlet and outlet lines) and the plumbing associated with the recirculation system. Additionally, the volume of the process chamber 310 can be designed to be small compared to the volume of the plumbing outside of the processing chamber (such as inlet and outlet lines) and the plumbing associated with the recirculation system.

The high pressure fluid and the process chemistry can be circulated until they are deemed fully mixed. The mixing of the high pressure fluid and the process chemistry is performed prior to exposing the substrate to any process chemistry. For example, a flow meter, such as a Coriolis meter, can be utilized to monitor the flow of high pressure fluid and process chemistry through the bypass line 362. When flow variations (due to, for example, density variations) become less than a pre-determined value, the flow can be determined to be sufficiently mixed. At this time, the first and second valves 364, 366 can be opened to flow of high pressure fluid and process chemistry through processing chamber 310.

The high pressure fluid can include a supercritical fluid. Alternatively, the high pressure fluid includes carbon dioxide. Alternatively, the high pressure fluid includes supercritical carbon dioxide. Alternatively, the high pressure fluid includes liquefied carbon dioxide. The mixing of the high pressure fluid and the process chemistry can be performed in order to maintain the high pressure fluid in a supercritical state.

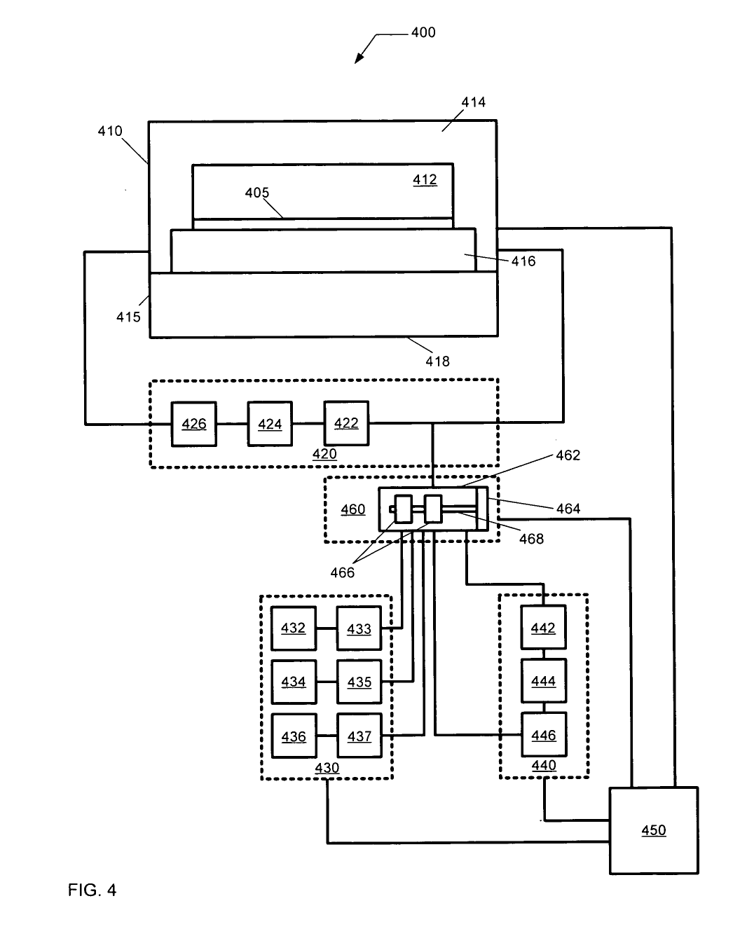

Referring now to FIG. 4, a high pressure processing system 400 is presented according to another embodiment. In the illustrated embodiment, high pressure processing system 400 comprises a processing chamber 410, a recirculation system 420, a pre-mixing system 460, a process chemistry supply system 430, a high pressure fluid supply system 440, and a controller 450, all of which are configured to process substrate 405. The controller 450 can be coupled to the processing chamber 410, the recirculation system 420, the pre-mixing system 460, the process chemistry supply system 430, and the high pressure fluid supply system 440. Alternately, controller 450 can be coupled to a one or more additional controllers/computers (not shown), and controller 450 can obtain setup and/or configuration information from an additional controller/computer.

As shown in FIG. 4, the recirculation system 420 can include a recirculation fluid heater 422, a pump 424, and a filter 426. Additionally, the process chemistry supply system 430 can include one or more chemistry introduction systems, each introduction system having a chemical source 432, 434, 436, and an injection system 433, 435, 437. The injection systems 433, 435, 437 can include a pump and an injection valve. Furthermore, the high pressure fluid supply system 440 can include a supercritical fluid source 442, a pumping system 444, and a supercritical fluid heater 446. Moreover, one or more injection valves, or exhaust valves may be utilized with the high pressure fluid supply system.

Also shown in FIG. 4, the pre-mixing system 460 comprises a mixing chamber 462 coupled to the high pressure fluid supply system 440 and the process chemistry supply system 430, and configured to receive the high pressure fluid and the process chemistry, respectively. Additionally, the pre-mixing system 460 can include an agitator for agitating the high pressure fluid and the process chemistry within the mixing chamber 460. For example, a drive system 464, and one or more mixing vanes 466 coupled to the drive system 464 via a shaft 468 can be utilized to stir the high pressure fluid and the process chemistry and promote mixing. The high pressure fluid and the process chemistry can be agitated until they are deemed fully mixed. The mixing of the high pressure fluid and the process chemistry is performed prior to exposing the substrate to any process chemistry.

Once the high pressure fluid and the process chemistry are mixed, the mixed fluid can be introduced to the processing chamber 410. When the mixed fluid is introduced to the processing chamber 410, the mixing chamber 462 can be back-filled with additional high pressure fluid in order to maintain a pre-determined pressure in the mixing chamber 462.

The high pressure fluid can include a supercritical fluid. Alternatively, the high pressure fluid includes carbon dioxide. Alternatively, the high pressure fluid includes supercritical carbon dioxide. Alternatively, the high pressure fluid includes liquefied carbon dioxide. The mixing of the high pressure fluid and the process chemistry can be performed in order to maintain the high pressure fluid in a supercritical state.

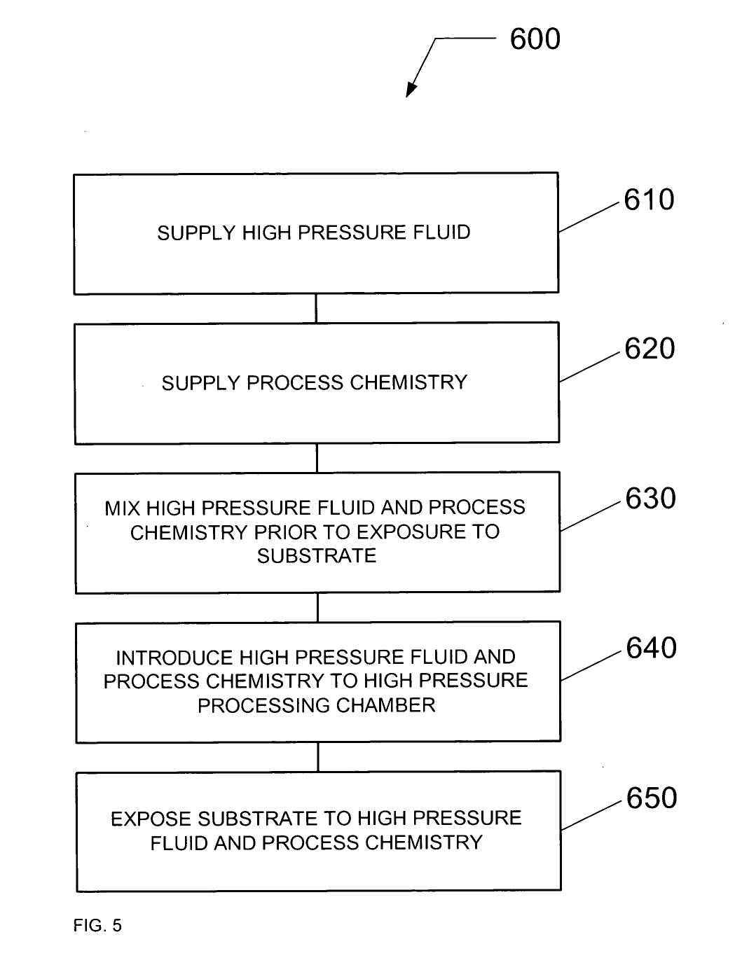

Referring now to FIG. 5, a method for processing a substrate in a high pressure processing system is described. The method includes a flow chart 600 beginning in 610 with supplying a high pressure fluid to a pre-mixing system. In one example, the high pressure fluid is introduced to the processing chamber, and the plumbing outside of the processing chamber including the recirculation system. The high pressure fluid may or may not be circulated through the processing chamber. Prior to introducing process chemistry, one or more valves are closed to prevent exposure of a substrate in the processing chamber to process chemistry, and the high pressure fluid is circulated through the bypass line. In another example, the high pressure fluid is introduced to a mixing chamber.

In 620, a process chemistry, such as one described above, is supplied to the pre-mixing system. In the former example, the process chemistry is added to the high pressure fluid, and circulated through the bypass line. In the latter example, the process chemistry is added to the high pressure fluid in the mixing chamber.

In 630, the high pressure fluid and the process chemistry are mixed in the pre-mixing system prior to exposing the substrate to the process chemistry. In the former example, the process chemistry is circulated through the bypass line until the high pressure fluid and the process chemistry are mixed. In the latter example, the high pressure fluid and the process chemistry are mixed in the mixing chamber using, for instance, the agitator for agitating or stirring the two or more fluids.

In 640, the high pressure fluid and the process chemistry are introduced to the high pressure processing system. In the former example, the one or more valves are opened to the processing chamber, and the mixed high pressure fluid and process chemistry are introduced to the substrate in the processing chamber. In the latter example, the mixed high pressure fluid and process chemistry are introduced to the substrate in the processing chamber from the mixing chamber.

In 650, the substrate is treated by exposing the substrate to the high pressure fluid and the process chemistry.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A high pressure processing system for treating a substrate comprising:
a processing chamber configured to treat said substrate with a fluid, introduced therein, having substantially supercritical fluid properties;
a high pressure fluid supply system configured to introduce a high pressure fluid to said processing chamber;
a process chemistry supply system configured to introduce a process chemistry to said processing chamber;
a pre-mixing system coupled to said processing chamber, and configured to receive said high pressure fluid from said high pressure fluid supply system and said process chemistry from said process chemistry supply system and mix said high pressure fluid and said process chemistry prior to introducing said high pressure fluid and said process chemistry to said processing chamber; and
a fluid flow system coupled to said processing chamber, and configured to circulate said high pressure fluid and said process chemistry through said processing chamber over said substrate.

2. The high pressure processing system of claim 1, wherein said high pressure fluid flow system is a recirculation system configured to recirculate to said inlets fluid removed from said processing chamber by said outlets.

3. The high pressure processing system of claim 1, wherein said fluid includes carbon dioxide (CO₂).

4. The high pressure processing system of claim 1, wherein said process chemistry supply system is configured to introduce a solvent, a co-solvent, a surfactant, a film-forming precursor, or a reducing agent, or any combination thereof.

5. The high pressure processing system of claim 1, wherein said process chemistry supply system is configured to introduce: cleaning compositions for removing contaminants, residues, hardened residues, photoresist, hardened photoresist, post-etch residue, post-ash residue, post chemical-mechanical polishing (CMP) residue, post-polishing residue, or post-implant residue, or any combination thereof; cleaning compositions for removing particulate; drying compositions for drying thin films, porous thin films, porous low dielectric constant materials, or air-gap dielectrics, or any combination thereof; film-forming compositions for preparing dielectric thin films, metal thin films, or any combination thereof; or any combination thereof.

6. The high pressure processing system of claim 1, wherein said pre-mixing system comprises a bypass line and one or more valves such that when said one or more valves is closed to a flow of high pressure fluid and process chemistry through said processing chamber, said flow passes through said bypass line.

7. The high pressure processing system of claim 6, wherein said pre-mixing system further comprises a flow meter coupled to said bypass line, and configured to determine when said high pressure fluid and said process chemistry are mixed.

8. The high pressure processing system of claim 1, wherein said recirculation system comprises a pump.

9. The high pressure processing system of claim 8, wherein said recirculation system further comprises a heater, and a filter.

10. The high pressure processing system of claim 8, wherein said pre-mixing system comprises a bypass line having one end coupled to an outlet side of said pump and an opposite end coupled to an inlet side of said pump, and one or more valves coupled to said bypass line and configured to open and close said processing chamber to a flow of high pressure fluid and process chemistry.

11. The high pressure processing system of claim 1, wherein said pre-mixing system comprises a mixing chamber configured to receive said high pressure fluid and said process chemistry, and mix said high pressure fluid and said process chemistry.

12. The high pressure processing system of claim 11, wherein said pre-mixing system further comprises means for agitating said high pressure fluid and said process chemistry in said mixing chamber.

13. A method of processing a substrate in a high pressure processing system comprising:
supplying a high pressure fluid for use in said high pressure processing system;
supplying a process chemistry for use in said high pressure processing system;
mixing said high pressure fluid and said process chemistry prior to introducing said high pressure fluid and said process chemistry to said high pressure processing system;
introducing said high pressure fluid and said process chemistry to said high pressure processing system; and
exposing said substrate to said high pressure fluid and said process chemistry in said high pressure processing system by bringing the fluid to a state having substantially supercritical fluid properties and exposing the substrate to the fluid in that state.

14. The method of claim 13, wherein said supplying said high pressure fluid includes recirculating a supercritical fluid through said processing system.

15. The method of claim 14, wherein said high pressure fluid is high pressure carbon dioxide and said exposing of said substrate includes exposing said substrate to supercritical carbon dioxide (CO₂).
